(19) United States
(12) Patent Application Publication
(10) Pub. No.: US 2009/0127106 A1
(43) Pub. Date: May 21, 2009

(54) MAGNET CHOIR DESIGN FOR TARGET MATERIAL EROSION

(76) Inventor: Andrew Contes, Chandler, AZ (US)

Correspondence Address: COOL PATENT, P.C.;c/o CPA Global, P.O. BOX 52050, MINNEAPOLIS, MN, 55402, US

(21) Appl. No.: 11/940,441

(22) Filed: Nov. 15, 2007

(51) Int. Cl. C23C 14/22

(52) U.S. Cl. 204/298.12; 204/192.1

(57) ABSTRACT

A magnetic choir layout capable of enabling material erosion from a target providing a substantially uniform wear pattern.

### BACKGROUND

FIG. 1 illustrates a side view of a Physical Vapor Deposition (PVD) vacuum chamber 100. In a particular embodiment, integrated circuits may be fabricated in or on semiconductor wafer 108 which may comprise a variety of materials including silicon, gallium arsenide and indium phosphide, for example. During fabrication, silicon wafer 108 may be diced, so that areas of functioning integrated circuitry may be separated into individual microelectronic die 102. Microelectronic die 102 may be used in packaged microelectronic devices.

Semiconductor wafer 108 may comprise backside metallization layer 106 on back surface 104. In a particular embodiment, backside metallization layer 106 may be fabricated by sputtering a material onto back surface 104 of semiconductor wafer 100 via PVD. In a particular embodiment, backside metallization layer 106 may comprise one or more materials such as, for instance, gold, titanium, and/or nickel/vanadium. After dicing, backside metallization layer 106 may enable coupling of back surface 104 of microelectronic die 102 to other surfaces for assembly. For instance, in a particular embodiment, microelectronic die 102 may be attached to a heat dissipation device (not shown) via backside metallization layer 106 by a thermal interface material. Such thermal interface materials may comprise solder materials such as, for instance, lead, tin, indium, silver, copper, and alloys thereof.

In a particular embodiment, PVD takes place in vacuum chamber 100 by bombarding target 116 with ions 112 emitted from a rare gas discharge 114. During PVD, a gas is released into vacuum chamber 100 and ionized and a negative voltage is applied to target 116. When ions 112 with high kinetic energy are incident on target 116, the subsequent collisions knock loose atoms 118 from the target 116. These atoms 118 settle on back surface 104 of semiconductor wafer 108 and vacuum chamber 100 walls. In a particular embodiment, during PVD, rod 120 comprising magnetic choir 122 rotates behind target 116 as target 116 is bombarded with ions 112. Rod 120 and magnetic choir 122 may attract ions toward target 116.

### BRIEF DESCRIPTION OF THE DRAWINGS

FIG. 1 is a side view of a particular embodiment of a PVD vacuum chamber.

FIG. 2 is an exploded view of a particular embodiment of a rod and target assembly.

FIG. 3 is an exploded view of a particular embodiment of a rotatable member and target assembly.

FIG. 4 is a diagram of a particular embodiment of a rotatable member, processor and controller assembly.

### DETAILED DESCRIPTION

In the following detailed description, numerous specific details are set forth in order to provide a thorough understanding of claimed subject matter. However, it will be understood by those skilled in the art that claimed subject matter may be practiced without these specific details. In other instances, well-known methods, procedures, and components have not been described in detail so as not to obscure claimed subject matter.

Throughout the following disclosure the term ‘target’ is intended to refer to a cathode of solid material used in a PVD process. The term ‘sputtering’ is used throughout the text to mean eroding target material and depositing it onto a substrate. The term ‘magnetic choir’ is used throughout the text and is intended to refer to the physical layout of one or more magnets. The term ‘monitor’ is used throughout the text and is intended to mean a device, or arrangement capable of observing, detecting, estimating or recording an event or action such as a wear pattern on a target.

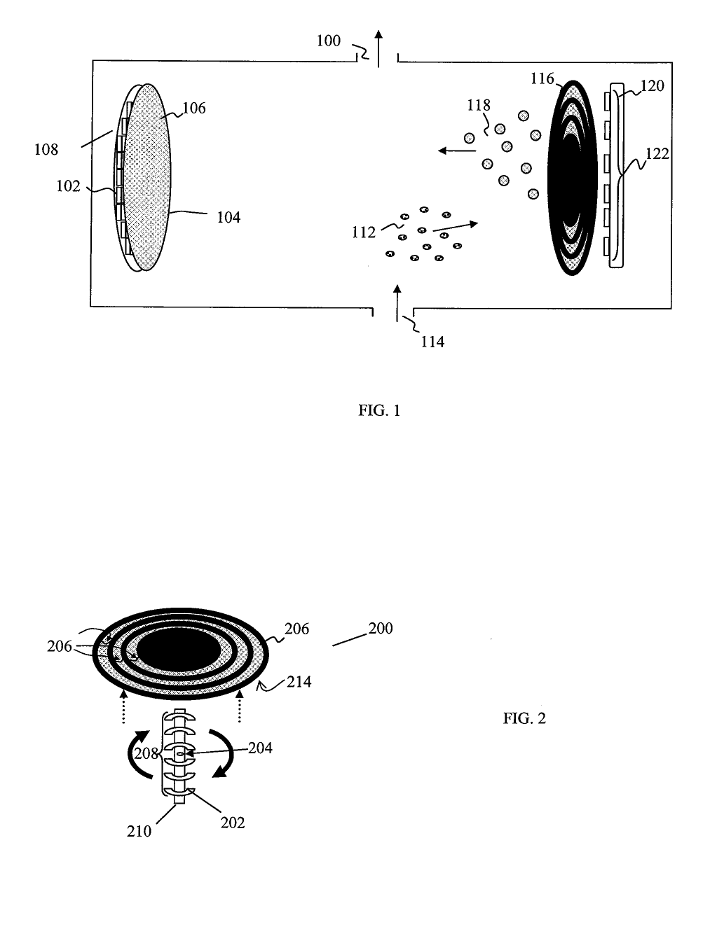

FIG. 2 is an exploded view of assembly 200 comprising rod 210 and target 206 for use in backside metallization via PVD. As discussed above, one or more metal layers may be deposited onto a back surface of a semiconductor wafer via PVD by removal of a deposition material from target 206 and depositing the material on the backside of a semiconductor wafer. In a particular embodiment, during PVD, rod 210 comprising magnetic choir 208 may rotate behind target 206 as target 206 is bombarded with ions. In a particular embodiment, rod 210 may rotate about axis 204 in a clockwise or counterclockwise direction in a plane parallel with back surface 214 of target 206. Conventionally, magnetic choir 208 may comprise a plurality of magnets 202 in a fixed layout. In a particular embodiment, a plurality of magnets may be used, rather than one large magnet, to provide more control of the magnetic field distribution. Multiple smaller magnets 202 may decrease the chance for failure and increases reliability and magnetic field control so that the function may be performed for a greater amount of time. According to a particular embodiment, magnets 202 may attract ions toward target 206. Rotation of rod 210 also generates a helical path for electrons to travel, increasing the probability of ionization of gas atoms and increasing the sputter rate. However, this is merely an example of a PVD process and claimed subject matter is not so limited.

In a particular embodiment, as rod 210 rotates, each magnet 202 sweeps a circular path behind target 206. The circles swept by magnets 202 are concentric and do not overlap. Because the ions are attracted to the magnets, more of the target 206 material directly above the circles swept by magnets 202 is eroded. Thus, the spinning of magnetic choir 208 generates racetrack wear pattern 212 on target 206. After a number of PVD cycles, racetrack wear pattern 212 reaches a particular depth and begins to disrupt the PVD process. Therefore, target 206 is typically replaced before a substantial amount of material is used. Replacing target 206 before a substantial amount of the material has been used is costly and inefficient.

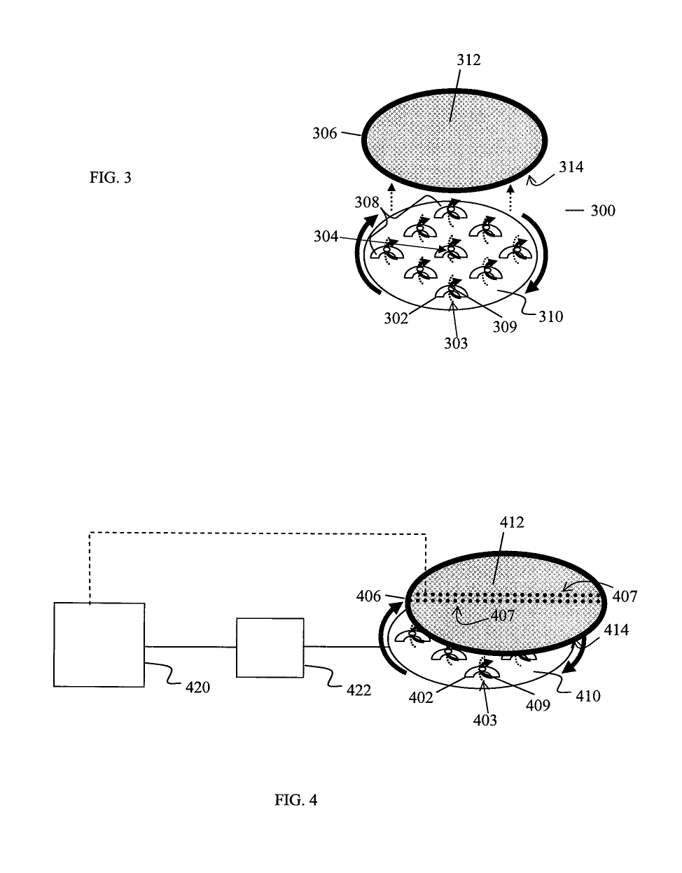

FIG. 3 is an exploded view of assembly 300 comprising rotatable member 310 and target 306 for use in backside metallization. In a particular embodiment, rotatable member 310 may comprise a variety shapes such as, for instance; square, circular, triangular, concave, convex and/or rectangular and the scope of the claimed subject matter is not limited in this respect. According to a particular embodiment, rotatable member 310 may be positioned proximate to target 306 a distance of about 1.00 cm to 20.00 cm. In a particular embodiment, rotatable member 310 may be capable of rotating behind target 306 and may comprise a magnetic choir 308. According to a particular embodiment, magnetic choir 308 may comprise a plurality of magnets 302 in a fixed or dynamic layout. Rotatable member 310 may rotate about axis 304 in a clockwise or counterclockwise direction in a plane parallel to back surface 314 of target 306. As rotatable member 310 rotates, magnets 302 may sweep through overlapping concentric circles. Again, because ions are attracted to magnets 302, more target 306 material is eroded directly above the circles swept by magnets 302. However, in contrast to the process discussed with reference to FIG. 2, because the circles swept by magnets 302 overlap, magnetic choir 308 may generate a substantially uniform wear pattern 312 over top surface 307 of target 306. This may allow more material of target 306 to be eroded during a PVD process before target 306 is worn to a point that may necessitate replacement. This may increase the number of PVD cycles for which target 306 may be used before it becomes ineffective thus lowering the cost and increasing the efficiency of the overall PVD process. However, this is merely an example of a magnetic choir arrangement and rotatable member capable of enabling a substantially uniform target wear pattern and claimed subject matter is not so limited.

In a particular embodiment, magnets 302 may be coupled to rotatable member 310 by a variety of methods, such as by an actuator 309. In a particular embodiment, actuator 309 may comprise a variety of devices such as, for instance, fasteners, pins, rods, screws and/or studs. In a particular embodiment, magnets 302 may rotate in a clockwise or counterclockwise direction about actuator 309. By adding an additional degree of rotation, coverage of the surface area swept by magnets 302 may be increased. As discussed above, rotation of rotatable member 310 generates a helical path for the electrons to travel, increasing the probability of ionization of gas atoms and increasing the sputter rate. According to a particular embodiment, rotation of individual magnets 302 may generate additional helical paths for the electrons to travel further increasing the probability of ionization of gas atoms and further increasing the sputter rate. However this is merely an example of a magnet choir layout and magnet rotation and claimed subject matter is not so limited.

In a particular embodiment, a magnetic choir layout 308 of magnets 302 may be adjusted by changing a position of one or more magnets 302. For the purposes of clarity changing the position of a single magnet 302 will be discussed herein. However, the position of one or more magnets 302 may be adjusted and claimed subject matter is not limited to adjustment of a single magnet.

As discussed above, a magnet 302 may be coupled to member 310 via an actuator 309. According to a particular embodiment, actuator 309 may be positioned on or within guide 303. Positioning actuator 309 within guide 303 on rotatable member 310 may enable actuator 309 to change a position of a magnet 302 at any time, such as, before or during PVD processing. In a particular embodiment, actuator 309 may move magnet 302 from a first position along guide 303 to a second position along guide 303. According to an alternative embodiment, magnet 302 may be moved to multiple positions or may be moved with a continuous and fluid motion from a starting position at one end of guide 303 to a final position at an opposite end of guide 303. However, these are merely examples of magnet position adjustments or changes and claimed subject matter is not so limited.

According to a particular embodiment, guide 303 may comprise one or more tracks, rails, slots and/or grooves. As discussed above, actuator 309 may change the position of magnet 302 by moving within guide 303. According to a particular embodiment, a variety of forces may be applied to actuator 309 to move magnet 302. Such forces may be, for instance, mechanical, electrical, magnetic, electromechanical, electromagnetic, hydraulic and/or pneumatic. However, these are merely examples of forces that may be applied to an actuator to adjust a position of a magnet and claimed subject matter is not so limited.

FIG. 4 illustrates a particular embodiment of member 410 and actuator 409 coupled to controller 422 and processor 420. According to a particular embodiment, positioning of one or more actuators 409 may be controlled by one or more processors. For the purposes of clarity a single processor 420, single controller 422 and single actuator 409 will be discussed herein, however, claimed subject matter is not limited to embodiments comprising a single processor 420, single controller 422 and single actuator 409.

In a particular embodiment, processor 420 may be coupled to controller 422 which may be coupled to actuator 409. According to a particular embodiment, controller 422 may be capable of controlling positioning of actuator 409 along guides 403. In a particular embodiment, processor 420 may be capable of generating positioning parameters. Such positioning parameters may be pre-set, user defined and/or dynamic. In a particular embodiment, pre-set positioning parameters may be programmed into hardware and/or software running on processor 420. In a particular embodiment, user defined positioning parameters may be provided by a user via a user interface at any time before or during PVD processing. According to a particular embodiment, dynamic positioning parameters may be determined by processor 420 during PVD processing based on target wear information generated by a target wear monitor such as sensors 407. In a particular embodiment, a target wear monitor, such as sensor 407, may be coupled to processor 420 and may communicate target wear information to processor 420. However, these are merely examples of methods of generating magnet positioning parameters and claimed subject matter is not so limited.

In a particular embodiment, processor 420 may generate dynamic positioning parameters based, at least in part, on target wear information provided by sensor 407. Sensor 407 may be capable of monitoring target 406 wear patterns 412 by a variety of methods. For instance, sensor 407 may be one or more, infrared sensors, white light interferometers, touch gages and/or In Process Gages (IPG). Alternatively, wear patterns 412 on target 406 may be monitored without sensors 407 coupled to target 406. In other embodiments, target wear monitors may comprise a variety of devices or indicators. For instance, a target wear pattern 412 may be monitored by a variety of methods such as by a kilowatt hour timer, laser monitor and/or computer modeling program. However, these are merely examples of methods of monitoring wear patterns on a target and claimed subject matter is not so limited.

In a particular embodiment, positioning parameters may be communicated from processor 420 to controller 422 for controlling positioning of one or more actuators 409. Alternatively, processor 420 may control positioning of actuator 409 without an intervening controller 422. However, these are merely examples of controlling positioning of an actuator with a processor and/or a controller and claimed subject matter is not so limited.

While certain features of claimed subject matter have been illustrated as described herein, many modifications, substitutions, changes and equivalents will now occur to those skilled in the art. It is, therefore, to be understood that the appended claims are intended to cover all such embodiments and changes as fall within the spirit of claimed subject matter.

What is claimed is:

1. An apparatus comprising:
a member for positioning proximate a target during physical vapor deposition (PVD) comprising an axis that is substantially central, the member being capable of rotation about the axis; and
two or more magnets positioned on a top surface of the member, the magnets being capable of sweeping through overlapping concentric circles if the member is rotated about the axis in a first order rotation.

2. The apparatus of claim 1 wherein the member further comprises at least one actuator capable of coupling at least one magnet to the member.

3. The apparatus of claim 2 wherein the at least one actuator is capable of changing the position of at least one magnet on the top surface of the member.

4. The apparatus of claim 2 wherein the at least one magnet is capable of rotating about the at least one actuator in a second order rotation.

5. The apparatus of claim 2 wherein the at least one actuator comprises at least one: fastener, pin, rod, screw or stud, or combinations thereof.

6. The apparatus of claim 2 wherein the member further comprises at least one guide disposed on the top surface of the member and wherein the at least one actuator is coupled to the member via the at least one guide.

7. The apparatus of claim 6 wherein the at least one guide comprises one or more: tracks, rails, slots or grooves, or combinations thereof.

8. The apparatus of claim 6 further comprising;
a processor capable of determining positioning parameters for positioning the at least one actuator.

9. The apparatus of claim 6 further comprising;
a processor capable of determining positioning parameters for positioning the at least one actuator, wherein the processor is capable of controlling movement of the one or more actuators based at least in part on the determined positioning parameters.

10. The apparatus of claim 8 further comprising;
a controller coupled to the processor, the controller capable of controlling movement of the one or more actuators based at least in part on positioning parameters received from the processor.

11. The apparatus of claim 8 further comprising;
at least one monitor for determining a wear pattern on a target, wherein the at least one monitor is capable of communicating information about the wear pattern on the target to the processor; and
wherein the positioning parameters are based at least in part on information about the wear pattern on the target received from the at least one monitor.

12. The apparatus of claim 11 wherein the at least one monitor comprises one or more: infrared sensors, white light interferometers, touch gages, In Process Gages (IPG), kilowatt hour timers, lasers or computer modeling programs, or combinations thereof.

13. A method comprising:
eroding material from a surface of a target during PVD using a member comprising a magnetic choir;
controlling a wear pattern on the surface of the target based at least in part on the magnetic choir layout, said controlling comprising dynamically changing a layout of the magnetic choir during said eroding; and
generating a substantially uniform wear pattern on the surface of the target material, said generating being based at least in part on said controlling the wear pattern.

14. The method of claim 13 wherein dynamically changing a layout of the magnetic choir further comprises;
generating parameters for positioning the magnetic choir layout based at least in part on: pre-set position parameters, user defined position parameters or dynamic position parameters, or combinations thereof; and
adjusting the magnetic choir layout based at least in part on the parameters.

15. The method of claim 13 wherein controlling the wear pattern further comprises;
monitoring the wear pattern;
generating wear pattern information; and
adjusting the magnetic choir layout based at least in part on the wear pattern information.
